(19) United States
(12) Patent Application Publication
(10) Pub. No.: US 2024/0379914 A1
(43) Pub. Date: Nov. 14, 2024

(54) DISPLAY DEVICE

(71) Applicant: Samsung Display Co., LTD., Yongin-si (KR)

(72) Inventors: Gi Hoon YANG, Yongin-si (KR); JEONGSOO KIM, Yongin-si (KR); Hyung Guen YOON, Yongin-si (KR); Minseok LEE, Yongin-si (KR); Ho LIM, Yongin-si (KR); Suk-Kung CHEI, Yongin-si (KR)

(21) Appl. No.: 18/417,055

(22) Filed: Jan. 19, 2024

(30) Foreign Application Priority Data
May 11, 2023 (KR) 10-2023-0061273

(51) Int. Cl. H01L 33/50; H01L 25/075; H01L 33/44

(52) U.S. Cl. CPC H01L 33/505; H01L 25/0753; H01L 33/44

(57) ABSTRACT

A display device includes: a display unit; and a color converter on the display unit and including a color converting layer and a transmission layer, a bank between the color converting layer and the transmission layer, a first layer on the color converting layer, the transmission layer, and the bank, a second layer on the first layer, a third layer on the second layer, and a color filter on the third layer. The first layer includes a first sub-layer with a first refractive index equal to or greater than about 1.4 and less than about 1.8, and a second sub-layer with a second refractive index equal to or greater than about 1.8 and equal to or less than about 2.0. The second layer has a refractive index smaller than those of the first layer. The third layer has a refractive index greater than that of the second layer.

This application claims priority to Korean Patent Application No. 10-2023-0061273, filed on May 11, 2023, and all the benefits accruing therefrom under 35 U.S.C. § 119, the content of which in its entirety is herein incorporated by reference.

### BACKGROUND

### (a) Field

The disclosure relates to a display device, and particularly relates to a display device for increasing an amount of light provided to a color converting layer.

### (b) Description of the Related Art

A light-emitting element is an element in which holes supplied from an anode and electrons supplied from a cathode are combined in an organic emission layer to form excitons, and light is emitted while the excitons are stabilized.

The light-emitting element has several merits such as a wide viewing angle, a relatively fast response speed, a relatively thin thickness, and relatively low power consumption such that a light-emitting diode is widely applied to various electrical and electronic devices such as televisions, monitors, and mobile phones.

Recently, to realize display devices with relatively high efficiency, display devices including color converting layers are being proposed. The color converting layer may convert incident light into different colors.

### SUMMARY

The disclosure attempts to provide a display device for reflecting blue light that is not converted and is output toward a color converting layer and increasing an amount of blue light provided to the color converting layer.

An embodiment of the disclosure provides a display device including: a display unit disposed on a substrate; and a color converter disposed on the display unit. The color converter includes a color converting layer and a transmission layer, a bank disposed between the color converting layer and the transmission layer, a first layer disposed on the color converting layer, the transmission layer, and the bank, a second layer disposed on the first layer, a third layer disposed on the second layer, and a color filter disposed on the third layer, the first layer includes a first sub-layer with a first refractive index, and a second sub-layer with a second refractive index, the first refractive index is equal to or greater than about 1.4 and less than about 1.8, and the second refractive index is equal to or greater than about 1.8 and equal to or less than about 2.0. The second layer has a refractive index smaller than the first refractive index of the first layer. The third layer has a refractive index greater than the refractive index of the second layer.

In an embodiment, the first sub-layer may have a thickness of about 50 nanometers to about 300 nanometers.

In an embodiment, the second sub-layer may have a thickness of about 50 nanometers to about 300 nanometers.

In an embodiment, the first sub-layer may include silicon oxynitride or silicon oxide.

In an embodiment, the second sub-layer may include silicon nitride.

In an embodiment, the first sub-layer and the second sub-layer may be alternately repeatedly stacked twice to six times.

In an embodiment, the first sub-layer and the second sub-layer may be alternately repeatedly stacked twice or three times.

In an embodiment, the display device may further include a first overcoat layer disposed on the color filter.

In an embodiment, the first overcoat layer may have a refractive index of about 1.45 to about 1.55, and the first overcoat layer may have a thickness of about 5 micrometers to about 15 micrometers.

In an embodiment, the display device may further include a low reflection layer disposed on the first overcoat layer.

In an embodiment, the low reflection layer may include a first organic layer disposed on the first overcoat layer, a second organic layer disposed on the first organic layer, and a second overcoat layer disposed on the second organic layer.

In an embodiment, the first organic layer may have a refractive index of about 1.6 to about 1.7, the second organic layer may have a refractive index of about 1.8 to about 2.0, and the second overcoat layer may have a refractive index of about 1.25 to about 1.30.

In an embodiment, the first organic layer may have a thickness of about 50 nanometers to about 100 nanometers, the second organic layer may have a thickness of about 100 nanometers to about 150 nanometers, and the second overcoat layer may have a thickness of about 60 nanometers to about 110 nanometers.

In an embodiment, the low reflection layer may include a first inorganic layer disposed on the first overcoat layer, a second inorganic layer disposed on the first inorganic layer, a third inorganic layer disposed on the second inorganic layer, a fourth inorganic layer disposed on the third inorganic layer, and a third overcoat layer disposed on the fourth inorganic layer.

In an embodiment, the first inorganic layer may have a refractive index of about 1.8 to about 2.0, the second inorganic layer may have a refractive index of about 1.4 to about 1.5, the third inorganic layer may have a refractive index of about 1.8 to about 2.0, the fourth inorganic layer may have a refractive index of about 1.4 to about 1.5, and the third overcoat layer may have a refractive index of about 1.25 to about 1.30.

In an embodiment, the first inorganic layer may have a thickness of about 10 nanometers to about 30 nanometers, the second inorganic layer may have a thickness of about 10 nanometers to about 30 nanometers, the third inorganic layer may have a thickness of about 100 nanometers to about 150 nanometers, the fourth inorganic layer may have a thickness of about 10 nanometers to about 30 nanometers, and the third overcoat layer may have a thickness of about 60 nanometers to about 110 nanometers.

In an embodiment, the first layer may reflect light with a wavelength of 440 nanometers to 460 nanometers.

Another embodiment of the disclosure provides a display device including: a light-emitting diode disposed on a substrate; and a color converter disposed on the light-emitting diode. The color converter includes a color converting layer and a transmission layer, a bank disposed between the color converting layer and the transmission layer, a first layer contacting upper sides of the color converting layer, the transmission layer, and the bank, and a color filter disposed on the first layer, the first layer includes a first sub-layer with a first refractive index, and a second sub-layer with a second refractive index, and the first refractive index is equal to or greater than about 1.4 and less than about 1.8, and the second refractive index is equal to or greater than about 1.8 and equal to or less than about 2.0.

In an embodiment, the display device may further include a second layer disposed on the first layer and having a refractive index smaller than the first refractive index of the first layer, and a third layer disposed on the second layer and having a refractive index greater than the refractive index of the second layer.

In an embodiment, the second layer may have a refractive index of about 1.20 to about 1.30, and the third layer may have a refractive index of about 1.45 to about 1.70.

In an embodiment, the second layer may have a thickness of about 1 micrometer to about 3 micrometers, and the third layer may have a thickness of about 300 nanometers to about 500 nanometers.

In an embodiment, the bank may have a thickness of about 6 micrometers to about 12 micrometers.

In an embodiment, the first sub-layer and the second sub-layer may be alternately repeatedly stacked.

By the embodiments, the display device for reflecting blue light that is not converted and is output toward a color converting layer and increasing an amount of blue light provided to the color converting layer may be provided. By the embodiments, the amount of light converted by the color converting layer may be increased and the light outputting efficiency may be increased.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 shows an exploded perspective view of an embodiment of a display device.

FIG. 2 shows a cross-sectional view of an embodiment of a display panel.

FIG. 3 to FIG. 11 show cross-sectional views of an embodiment of a display panel.

FIG. 12 to FIG. 14 show efficiency increasing graphs of an embodiment and a comparative example.

FIG. 15 shows an image of a comparative example of a display panel.

FIG. 16 shows an image of an embodiment of a display panel.

### DETAILED DESCRIPTION

Embodiments of the disclosure will be described more fully hereinafter with reference to the accompanying drawings, in which embodiments of the disclosure are shown. As those skilled in the art would realize, the described embodiments may be modified in various ways, all without departing from the spirit or scope of the disclosure.

Parts that are irrelevant to the description will be omitted to clearly describe the inventive concept, and the same elements will be designated by the same reference numerals throughout the specification.

The size and thickness of each configuration shown in the drawings are arbitrarily shown for better understanding and ease of description, but the disclosure is not limited thereto. In the drawings, the thicknesses of layers, films, panels, regions, etc., is enlarged for clarity. The thicknesses of some layers and areas are exaggerated for convenience of explanation.

It should be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless explicitly described to the contrary, the word “comprise,” and variations such as “comprises” or “comprising” should be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

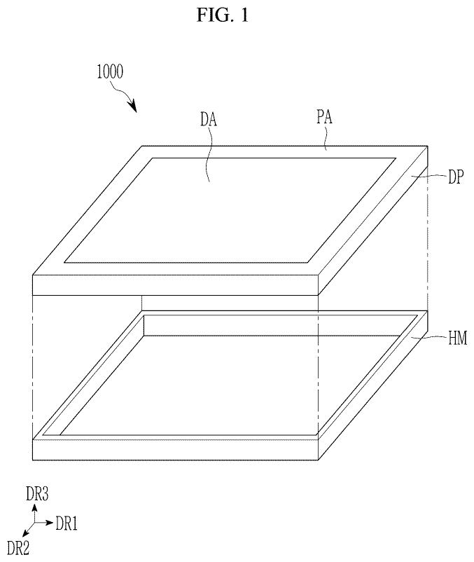

A display device in an embodiment will now be described with reference to FIG. 1. FIG. 1 shows an exploded perspective view of a display device.

Referring to FIG. 1, the display device 1000 may include a display panel DP and a housing HM.

One side of the display panel DP on which images are displayed is parallel to a side defined by a first direction DR1 and a second direction DR2. A normal direction of the one side on which the image is displayed—that is, a thickness direction of the display panel DP—is indicated by a third direction DR3. Front sides (or upper sides) and rear sides (or lower sides) of respective members are distinguished by the third direction DR3. However, the directions indicated by the first to third directions DR1, DR2, and DR3 are relative concepts, and may be converted into other directions.

The display panel DP may be a flat rigid display panel, but it is not limited thereto, and it may be a flexible display panel. The display panel DP may include of an organic light-emitting panel. However, a type of the display panel DP is not limited thereto, and the display panel DP may include various types of panels. In an embodiment, the display panel DP may include a liquid crystal panel, an electrophoretic display panel, or an electro-wetting display panel. The display panel DP may include next-generation display panels such as a micro light-emitting diode display panel, a quantum dot light-emitting diode display panel, or a quantum dot organic light-emitting diode display panel.

The micro the light-emitting diode (“LED”) display panel includes the LEDs with a size of about 10 micrometers (μm) to about 100 μm to configure respective pixels. The micro LED display panel has the merits that it may use an inorganic material, may omit a backlight, may have a fast reaction rate, may realize relatively high luminance with lower power, and may not be broken when it is bent.

The quantum dot LED display panel may be made by attaching a quantum dot-included film or forming with a quantum dot-included material. The quantum dot includes an inorganic material such as indium or cadmium, and it emits light and represents particles with a diameter equal to or less than several nanometers. The light of a desired color may be displayed by adjusting a particle size of the quantum dots. The quantum dot organic LED display panel is made by a blue organic light-emitting diode as a light source, and attaching a film including red and green quantum dots thereon or depositing a material including red and green quantum dots, thereby realizing the color. The display panel DP in an embodiment may include or consist of various sorts of display panels in addition to it.

As shown in FIG. 1, the display panel DP includes a display area DA for displaying images, and a non-display area PA provided near the display area DA. The non-display area PA displays no images. The display area DA may have a square shape, and the non-display area PA may have a shape surrounding the display area DA, for example. Without being limited thereto, the shapes of the display area DA and the non-display area PA may be relatively designed.

The housing HM provides a predetermined internal space. The display panel DP is installed in the housing HM. Various kinds of electronic parts, e.g., a power supply, a storage device, or a sound input and output module, may be installed in the housing HM in addition to the display panel DP.

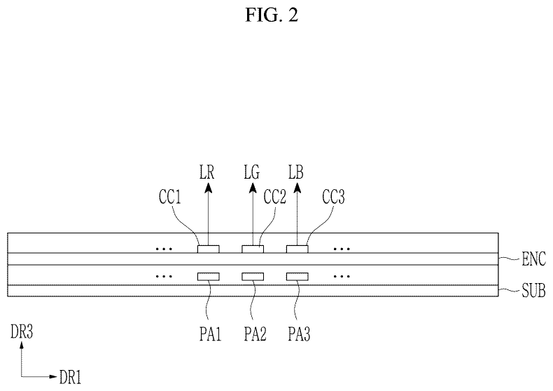

A display area of a display panel in an embodiment will now be described with reference to FIG. 2. FIG. 2 shows a cross-sectional view of an embodiment of a display panel.

Referring to FIG. 2, pixels PA1, PA2, and PA3 may be formed on a substrate SUB that corresponds to the display area DA of FIG. 1. The respective pixels PA1, PA2, and PA3 may include transistors and light-emitting diodes connected thereto.

An encapsulation layer ENC may be disposed on the pixels PA1, PA2, and PA3. The display area DA may be protected from external air or moisture through the encapsulation layer ENC. The encapsulation layer ENC may be integrally installed to overlap a front side of the display area DA, and a part thereof may be disposed in the non-display area PA.

A first color converter CC1, a second color converter CC2, and a transmitter CC3 may be disposed on the encapsulation layer ENC. The first color converter CC1 may overlap the first pixel PA1, the second color converter CC2 may overlap the second pixel PA2, and the transmitter CC3 may overlap the third pixel PA3.

Light emitted by the first pixel PA1 may pass through the first color converter CC1, and may be provided as red light LR. Light emitted by the second pixel PA2 may pass through the second color converter CC2, and may be provided as green light LG. Light emitted by the third pixel PA3 may pass through the transmitter CC3, and may be provided as blue light LB.

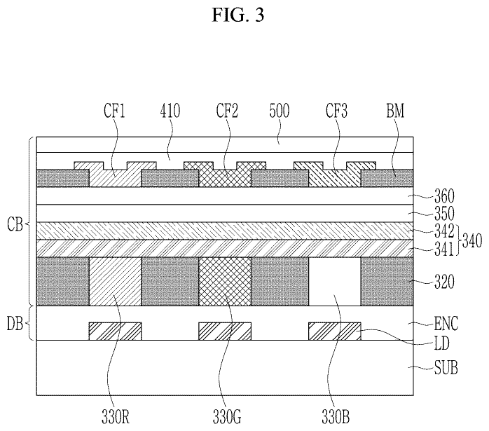

A display panel in an embodiment will now be described with reference to FIG. 3. FIG. 3 shows a cross-sectional view of an embodiment of a display panel.

Referring to FIG. 3, a display unit DB including a light-emitting diode LD and a color converter CB including color converting layers 330R and 330G, and a transmission layer 330B may be disposed on the substrate SUB.

The display unit DB includes a light-emitting diode LD disposed on the substrate SUB. The light-emitting diode LD may be an organic light-emitting element (“OLED”) or a nano light-emitting diode (“NED”), and is not limited thereto. The light-emitting diode LD may emit blue light.

An encapsulation layer ENC may be disposed on the light-emitting diode LD. The encapsulation layer ENC may be an insulating layer including an organic layer and/or an inorganic layer.

Banks 320, a red color converting layer 330R, a green color converting layer 330G, and a transmission layer 330B may be disposed on the encapsulation layer ENC. The red color converting layer 330R, the green color converting layer 330G, and the transmission layer 330B may overlap the light-emitting diode LD.

The banks 320 are disposed on the encapsulation layer ENC. The banks 320 may be spaced apart from each other with openings therebetween, and the respective openings may overlap color filters CF1, CF2, and CF3 in a direction that is vertical to the substrate SUB.

The banks 320 may include a black material to block light, and may prevent combination of colors between neighboring light-emitting regions.

The red color converting layer 330R, the green color converting layer 330G, and the transmission layer 330B are disposed among the banks 320 spaced apart from each other. The red color converting layer 330R may convert supplied light into the red color. The red color converting layer 330R may include quantum dots. The green color converting layer 330G may convert supplied light into the green color. The green color converting layer 330G may include quantum dots.

Maximum thicknesses of the red color converting layer 330R, the green color converting layer 330G, the transmission layer 330B, and the banks 320 may be about 3 μm to 12 μm. As a thickness of a first layer 340 to be described increases, the maximum thicknesses of the red color converting layer 330R, the green color converting layer 330G, the transmission layer 330B, and the banks 320 may be reduced. In an embodiment, they may be about 3 μm to about 8 μm.

The quantum dots will now be described in detail.

In the specification, the quantum dots (also referred to as semiconductor nanocrystals) may include a group II-VI compound, a group III-V compound, a group IV-VI compound, a group IV element or compound, a group I-III-VI compound, a group II-III-VI compound, a group I-II-IV-VI compound, or any combinations thereof.

The group II-VI compound may be selected from among a binary compound selected from among CdSe, CdTe, ZnS, ZnSe, ZnTe, ZnO, HgS, HgSe, HgTe, MgSe, MgS, and any combinations thereof; a tertiary compound selected from among AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any combinations thereof; and a quaternary compound selected from among HgZnTeS, CdZnSeS, CdZnSeTe, CdZnSTe, CdHgSeS, CdHgSeTe, CdHgSTe, HgZnSeS, HgZnSeTe, HgZnSTe, and any combinations thereof. The group II-VI compound may further include a group III metal.

The group III-V compound may be selected from among a binary compound selected from among GaN, GaP, GaAs, GaSb, AlN, AlP, AlAs, AlSb, InN, InP, InAs, InSb, and any combinations thereof; a tertiary compound selected from among GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and any combinations thereof; and a quaternary compound selected from among GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and any combinations thereof. The group III-V compound may further include a group II metal (e.g., InZnP).

The group IV-VI compound may be selected from among a binary compound selected from among SnS, SnSe, SnTe, PbS, PbSe, PbTe, and any combinations thereof; a tertiary compound selected from among SnSeS, SnSeTe, SnSTe, PbSeS, PbSeTe, PbSTe, SnPbS, SnPbSe, SnPbTe, and any combinations thereof; and a quaternary compound selected from among SnPbSSe, SnPbSeTe, SnPbSTe, and any combinations thereof.

The group IV element or compound may be selected from among a unary compound selected from among Si, Ge, and a combination thereof; and a binary compound selected from among SiC, SiGe, and a combination thereof.

The group I-III-VI compound may include CuInSe₂, CuInS₂, CuInGaSe, and CuInGaS, and is not limited thereto. The group I-II-IV-VI compound may include CuZnSnSe, and CuZnSnS, and is not limited thereto. The group IV element or compound may be selected from among a unary compound selected from among Si, Ge, and a mixture thereof; and a binary compound selected from among SiC, SiGe, and a mixture thereof.

The group II-III-VI compound may be selected from among ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and any combinations thereof, and is not limited thereto.

The group I-II-IV-VI compound may be selected from among CuZnSnSe and CuZnSnS, and is not limited thereto.

In an embodiment, the quantum dots may not include cadmium. The quantum dot may include a semiconductor nanocrystal based on the group III-V compound including indium and phosphorus. The group III-V compound may further include zinc. The quantum dot may include a semiconductor nanocrystal based on the group II-VI compound including a chalcogen (e.g., sulfur, selenium, tellurium, or a combination thereof) and zinc.

Regarding the quantum dot, the above-described binary compound, tertiary compound, and/or quaternary compound may exist in the particles with uniform concentration, or may exist in the same particles with a concentration distribution partially divided into some states. Further, the color converting layer may have a core/shell structure where one quantum dot surrounds another quantum dot. An interface between the core and the shell may have a concentration gradient such that a concentration of an element existing in the shell is gradually reduced nearing the center thereof.

In some embodiments, the quantum dot may have a core/shell structure including a core including the above-described nanocrystal and a shell surrounding the core. The shell of the quantum dot may function as a protective layer for maintaining the semiconductor characteristic by preventing chemical denaturation of the core and/or a charging layer for providing an electrophoretic characteristic to the quantum dot. The shell may be a single layer or a multilayer. An interface between the core and the shell may have a concentration gradient such that a concentration of the element existing in the shell is gradually reduced nearing the center thereof. In embodiments, the shell of the quantum dot include a metallic or non-metallic oxide, a semiconductor compound, or any combinations thereof.

The metallic or non-metallic oxide may exemplify binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, or tertiary compounds such as NiO, or MgAl₂O₄, CoFe₂O₄, NiFe₂O₄, or CoMn₂O₄, and the disclosure is not limited thereto.

The semiconductor compound may be exemplified by CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, and the disclosure is not limited thereto.

The interface between the core and the shell may have a concentration gradient such that a concentration of the element existing in the shell is gradually reduced nearing the center thereof. The semiconductor nanocrystal may have a structure including one semiconductor nanocrystal core and a multi-layered shell surrounding the semiconductor nanocrystal core. In an embodiment, the multi-layered shell may have two or more layers, e.g., two, three, four, five, or more layers. The two adjacent layers of the shell may have a single composition or different compositions. In the multi-layered shell, each layer may have a composition that varies along the radius.

The quantum dot may have a full width at half maximum of a light-emitting wavelength spectrum that is less than about 45 nanometers (nm), preferably less than about 40 nm, or more preferably less than about 30 nm, and it may improve color purity or color reproducibility within this range. Light emitted through the quantum dot is output in all directions, thereby improving a wide viewing angle.

Regarding the quantum dot, a shell material and a core material may have different energy bandgaps. In an embodiment, the energy bandgap of the shell material may be greater than the energy bandgap of the core material. In another embodiment, the energy bandgap of the shell material may be less than the energy bandgap of the core material. The quantum dot may have a multi-layered shell. Regarding the multi-layered shell, the energy bandgap of an outer layer may be greater than the energy bandgap of an inner layer (i.e., a layer that is near the core). Regarding the multi-layered shell, the energy bandgap of the outer layer may be less than the energy bandgap of the inner layer.

The quantum dots may adjust the absorption/emission wavelength by adjusting the composition and the size thereof. The maximum light-emitting peak wavelength of the quantum dots may have a wavelength range from ultraviolet to infrared or higher.

The quantum dots may have quantum efficiency of greater than or equal to about 10%, for example, greater than or equal to about 30%, greater than or equal to about 50%, greater than or equal to about 60%, greater than or equal to about 70%, greater than or equal to about 90%, or even about 100%. The quantum dots may have a relatively narrow spectrum. The quantum dots may have a full width at half maximum of emission wavelength spectrum, e.g., less than or equal to about 50 nm, less than or equal to about 45 nm, less than or equal to about 40 nm, or less than or equal to about 30 nm.

The quantum dot has a particle size of equal to or greater than about 1 nm and equal to or less than about 100 nm. The particle size refers to a particle diameter or a diameter which is calculated under the assumption it has a spherical shape from a two dimensional (“2D”) image obtained from transmission electron microscope analysis. The quantum dots may have a particle size of about 1 nm to about 20 nm, e.g., equal to or greater than about 2 nm, equal to or greater than about 3 nm, or equal to or greater than about 4 nm, and equal to or less than about 50 nm, equal to or less than about 40 nm, equal to or less than about 30 nm, equal to or less than about 20 nm, equal to or less than about 15 nm, or equal to or less than about 10 nm. A shape of the quantum dot is not specifically limited. In an embodiment, the shape of the quantum dot may include a sphere, a polyhedron, a pyramid, a multipod, a square, a cuboid, a nanotube, a nanorod, a nanowire, a nanosheet, or any combinations thereof, for example, and is not limited thereto.

The quantum dots may be commercially available or may be appropriately synthesized. When quantum dots are colloid-synthesized, the particle sizes may be relatively freely controlled and also uniformly controlled.

The quantum dot may include an organic ligand (e.g., having a hydrophobic residue and/or a hydrophilic residue). The organic ligand residue may be combined with the surface of the quantum dot. The organic ligand may include RCOOH, RNH₂, R₂NH, R₃N, RSH, R₃PO, R₃P, ROH, RCOOR, RPO (OH)₂, RHPOOH, R₂POOH, or combinations thereof; here, R may independently be a C3 to C40 substituted or unsubstituted aliphatic hydrocarbon group such as a C3 to C40 (e.g., C5 to C24) substituted or unsubstituted alkyl group, or a substituted or unsubstituted alkenyl group, a C6 to C40 (e.g., C6 to C20) substituted or unsubstituted aromatic hydrocarbon group such as a C6 to C40 substituted or unsubstituted aryl group, or any combinations thereof.

In embodiments, the organic ligand may include thiol compounds such as methane thiol, ethane thiol, propane thiol, butane thiol, pentane thiol, hexane thiol, octane thiol, dodecane thiol, hexadecane thiol, octadecane thiol, or benzyl thiol; amines such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; phosphine compounds such as methyl phosphine, ethyl phosphine, propyl phosphine, butyl phosphine, pentyl phosphine, octyl phosphine, dioctyl phosphine, tributyl phosphine, or trioctyl phosphine; phosphine compounds or their oxide compounds such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, diphenyl phosphine, a triphenyl phosphine compound or oxide compounds thereof, C5 to C20 alkyl phosphinic acids such as hexylphosphinic acid, octylphosphinic acid, dodecanephosphinic acid, tetradecanephosphinic acid, hexadecanephosphinic acid, octadecanephosphinic acid, and C5 to C20 alkyl phosphonic acids, and are not limited thereto. The quantum dot may include the organic ligand alone or as a combination of at least one kind. The hydrophobic organic ligand may not include a photopolymerizable residue (e.g., an acrylate or methacrylate).

The transmission layer 330B may be disposed on a portion that corresponds to the blue light-emitting region from among the spaces partitioned by the banks 320. The transmission layer 330B may include scatterers. The scatterers may be selected from among at least one of SiO₂, BaSO₄, Al₂O₃, ZnO, ZrO₂, and TiO₂. The transmission layer 330B may include a polymer resin and scatterers included in the polymer resin. In an embodiment, the transmission layer 330B may include TiO₂, for example, but is not limited thereto. The transmission layer 330B may transmit the light input from the light-emitting diode LD.

Regarding the display panel in the illustrated embodiment, the red color converting layer 330R converts incident light into the red color and outputs the same. The green color converting layer 330G converts incident light into the green color and outputs the same. However, the light input to the transmission layer 330B is not color-converted but transmits the same. The incident light may include blue light. The incident light may be blue light or may be a combination of blue light and green light. In an alternative embodiment, the incident light may include blue light, green light, and red light.

The first layer 340 may be disposed on the color converting layers 330R and 330G, the transmission layer 330B, and the banks 320. The first layer 340 may contact the upper sides of the color converting layers 330R and 330G, the transmission layer 330B, and the banks 320. The first layer 340 may be disposed on the color converting layers 330R and 330G, the transmission layer 330B, and the banks 320.

The first layer 340 may protect the color converting layers 330R and 330G, the transmission layer 330B, and the banks 320. The first layer 340 may reflect the blue light that is not converted by the color converting layers 330R and 330G but is transmitted toward the color converting layers 330R and 330G. Reflectance of the blue light at the first layer 340 may be greater than reflectance of the red light. Reflectance of the blue light at the first layer 340 may be greater than reflectance of the green light. In detail, regarding the first layer 340, reflectance of the light in a wavelength range of about 440 nm to about 460 nm may be higher than reflectance of the light in other wavelength ranges. According to this, the amount of the blue light provided to the color converting layers 330R and 330G is increased as an effect, and hence, the light efficiency for converting the blue light into the red light or green light may also be increased.

The first layer 340 may be manufactured by various processes, and may be manufactured by processes at the temperature of equal to or lower than 200 degrees Celsius (° C.). In an embodiment, the first layer 340 may be manufactured by the process at the temperature of equal to or lower than 90° C., for example.

The first layer 340 may include a first sub-layer 341 and a second sub-layer 342. The first sub-layer 341 may be disposed on the color converting layers 330R and 330G, the transmission layer 330B, and the banks 320. The second sub-layer 342 may be disposed on the first sub-layer 341.

The thickness of the first sub-layer 341 may be 50 nm to 300 nm. The first sub-layer 341 may have a first refractive index. The first refractive index may be about 1.40 to about 1.80, e.g., the first refractive index may be about 1.40 to about 1.70. The first sub-layer 341 may include silicon oxynitride (SiON) or silicon oxide (SiOx), and without being limited thereto, it may include any types of materials for satisfying the refractive index. In an embodiment, when the first sub-layer 341 includes silicon oxynitride, the first refractive index of the first sub-layer 341 may be about 1.5 to about 1.8, and, in an embodiment, it may be about 1.6, for example. In another embodiment, when the first sub-layer 341 includes silicon oxide, the first refractive index of the first sub-layer 341 may be about 1.4 to about 1.5, and for example, it may be about 1.48.

The thickness of the second sub-layer 342 may be about 50 nm to about 300 nm. The second sub-layer 342 has a second refractive index, and the second refractive index may be about 1.8 to about 2.0. In an embodiment, the refractive index of the second sub-layer 342 may be about 1.86, for example. The second sub-layer 342 may include silicon nitride (SiNx), and without being limited thereto, it may include any types of materials for satisfying the refractive index.

The second refractive index of the second sub-layer 342 may be greater than the first refractive index of the first sub-layer 341. The first layer 340 with a structure in which two layers with different refractive indices are stacked in an embodiment may reflect the blue light, and may transmit the green light and the red light. The blue light not converted by the quantum dot on the color converting layers 330R and 330G but having been transmitted through the color converting layers 330R and 330G may be reflected on the first layer 340, and may be provided to the color converting layers 330R and 330G. The amount of the blue light provided to the color converting layers 330R and 330G may be increased as an effect, and an efficiency when the light is converted into the red light or the green light by the color converting layers 330R and 330G may be increased.

A second layer 350 may be disposed on the first layer 340. The refractive index of the second layer 350 may be about 1.20 to about 1.30, and, in an embodiment, it may be about 1.25 to about 1.30, for example. The second layer 350 may include an organic material, may include an inorganic material, or may include a combination of the organic material and the inorganic material. The second layer 350 may be a single layer or may be a multilayer.

The refractive index of the second layer 350 may be smaller than the refractive index of the first layer 340. In an embodiment, the refractive index of the second layer 350 may be smaller than the refractive indices of the first sub-layer 341 and the second sub-layer 342, for example.

The thickness of the second layer 350 may be about 1 μm to about 3 μm. In an embodiment, as the thickness of the first layer 340 increases, the thickness of the second layer 350 may be reduced, for example.

A third layer 360 may be disposed on the second layer 350. The third layer 360 may protect a layer disposed on a bottom surface of the third layer 360. The third layer 360 may include an inorganic material, and, in an embodiment, it may include silicon oxide or silicon oxynitride, for example. The refractive index of the third layer 360 may be about 1.45 to about 1.7. In an embodiment, when the third layer 360 includes silicon oxide, the refractive index of the third layer 360 may be about 1.48, for example. In another embodiment, when the third layer 360 includes silicon oxynitride, the refractive index of the third layer 360 may be about 1.6. The thickness of the third layer 360 may be about 300 nm to about 500 nm, e.g., it may be about 400 nm.

The red color filter CF1, the green color filter CF2, and the blue color filter CF3 may be disposed on the third layer 360.

The red color filter CF1 may overlap the red color converting layer 330R. The red color filter CF1 may transmit the red light having been transmitted through the red color converting layer 330R, and may absorb light with other wavelengths, thereby increasing purity of the red light discharged to the outside of the display device.

The green color filter CF2 may overlap the green color converting layer 330G. The green color filter CF2 may transmit the green light having been transmitted through the green color converting layer 330G, and may absorb light with other wavelengths, thereby increasing the purity of the green light discharged to the outside of the display device.

The blue color filter CF3 may overlap the transmission layer 330B. The blue color filter CF3 may transmit the blue light having been transmitted through the transmission layer 330B, and may absorb light with other wavelengths, thereby increasing the purity of the blue light discharged to the outside of the display device.

A light-blocking layer BM may be disposed among the adjacent red color filter CF1, the green color filter CF2, and the blue color filter CF3. At least some of the red color filter CF1, the green color filter CF2, and the blue color filter CF3 may overlap each other, or may include a black material to block light on the light-blocking layer BM.

A first overcoat layer 410 may be disposed on the red, green and blue color filters CF1, CF2, and CF3. The first overcoat layer 410 may include a hard material. The refractive index of the first overcoat layer 410 may be about 1.45 to about 1.55. The thickness of the first overcoat layer 410 may be about 5 μm to about 15 μm.

A low reflection layer 500 may be disposed on the first overcoat layer 410. The low reflection layer 500 may be provided in a film form, and may be attached to the first overcoat layer 410. The low reflection layer 500 may reduce the reflection of light input from the outside of the display device.

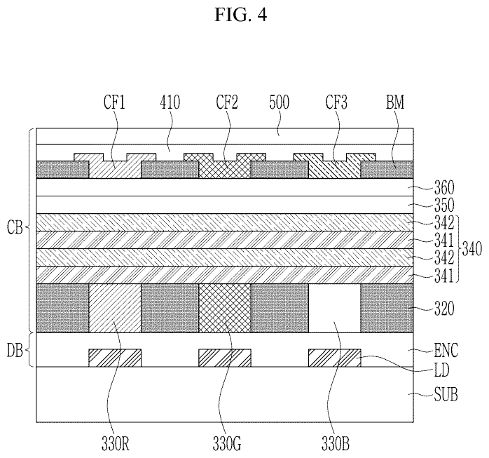

A display panel in an embodiment will now be described with reference to FIG. 4 to FIG. 11. FIG. 4 to FIG. 11 show cross-sectional views of a display panel. Descriptions on the same constituent elements as the above-noted constituent elements will be omitted.

Referring to FIG. 4, the first layer 340 may have a multilayered structure in which the first sub-layer 341, the second sub-layer 342, the first sub-layer 341, and the second sub-layer 342 are stacked. The first layer 340 may have a structure in which the first sub-layer 341 and the second sub-layer 342 are stacked twice.

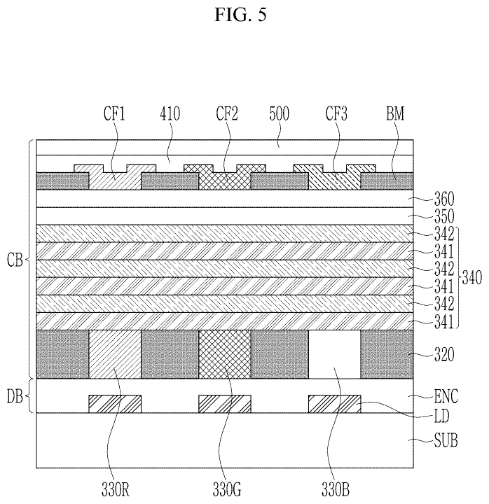

Referring to FIG. 5, the first layer 340 may have a multilayered structure in which the first sub-layer 341, the second sub-layer 342, the first sub-layer 341, the second sub-layer 342, the first sub-layer 341, and the second sub-layer 342 are stacked. The first layer 340 may have a structure in which the first sub-layer 341 and the second sub-layer 342 are stacked three times.

In an embodiment described with reference to FIG. 4 and FIG. 5, the thickness of the first sub-layer 341 may be 50 nm to 300 nm. The first sub-layer 341 may have a first refractive index. The first refractive index may be about 1.40 to about 1.80, and, in an embodiment, the first refractive index may be about 1.40 to about 1.65, for example. The first sub-layer 341 may include silicon oxynitride (SiON) or silicon oxide (SiOx), and without being limited thereto, it may include any types of materials for satisfying the refractive index. In an embodiment, when the first sub-layer 341 includes a silicon oxynitride, the refractive index of the first sub-layer 341 may be about 1.6, for example. In another embodiment, when the first sub-layer 341 includes a silicon oxide, the refractive index of the first sub-layer 341 may be about 1.48.

The thickness of the second sub-layer 342 may be about 50 nm to about 300 nm. The second sub-layer 342 has a second refractive index, and the second refractive index may be about 1.8 to about 2.0. In an embodiment, the refractive index of the second sub-layer 342 may be about 1.86, for example. The second sub-layer 342 may include silicon nitride (SiNx), and without being limited thereto, it may include any types of materials for satisfying the refractive index.

The second refractive index of the second sub-layer 342 may be greater than the first refractive index of the first sub-layer 341. The first layer 340 with the structure in which two layers with different refractive indices are stacked in an embodiment may reflect the blue light, and may transmit the green light and the red light. As the repeating number of the first sub-layer 341 and the second sub-layer 342 is increased, reflectance of the blue light may be increased. The repeating number of the first sub-layer 341 and the second sub-layer 342 may be twice to 6 times, and, in an embodiment, it may be twice to three times, for example. As the repeating number is increased, the reflectance of the blue light may be increased, and when the repeating number is greater than 6 times, the first layer 340 becomes substantially thick so the display panel may be bent, which is a problem.

The blue light not converted by the quantum dot on the color converting layers 330R and 330G but having been transmitted through the color converting layers 330R and 330G may be reflected on the first layer 340, and may be provided to the color converting layers 330R and 330G. The amount of the blue light provided to the color converting layers 330R and 330G may be increased as an effect, and efficiency when the light is converted into the red light or the green light by the color converting layers 330R and 330G may be increased.

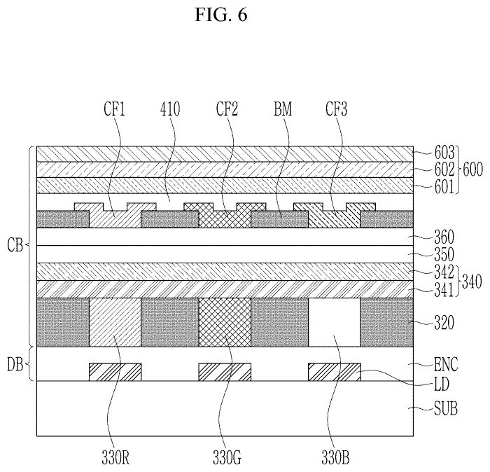

A display panel in an embodiment will now be described with reference to FIG. 6. A stacking structure below the first overcoat layer 410 in an embodiment of FIG. 6 corresponds to what is described in FIG. 3. The constituent elements disposed above the first overcoat layer 410 will now be described.

As shown in FIG. 6, the display panel may include a low reflection layer 600 disposed on the first overcoat layer 410. The low reflection layer 600 may correspond to an outermost layer of the display device. The low reflection layer 600 may reduce the reflection of the light input from the outside, and may provide images with excellent quality to a user. The low reflection layer 600 may be formed by a coating process. As no additional film is provided, the process may be simplified.

The low reflection layer 600 may be disposed on the first overcoat layer 410, and may include a first organic layer 601, a second organic layer 602, and a second overcoat layer 603 that are sequentially stacked.

The refractive index of the first organic layer 601 may be about 1.6 to 1.7. The thickness of the first organic layer 601 may be about 50 nm to about 100 nm. The refractive index of the second organic layer 602 may be about 1.8 to about 2.0. The thickness of the second organic layer 602 may be about 100 nm to about 150 nm. The refractive index of the second overcoat layer 603 may be about 1.25 to about 1.30. The thickness of the second overcoat layer 603 may be about 60 nm to about 110 nm.

The low reflection layer 600 may have a structure in which a middle refracting layer, a high refracting layer, and a low refracting layer are sequentially stacked with respect to the first overcoat layer 410. According to the stacking structure, the reflection of the light input toward the display panel from external light may be reduced, and improved displaying quality may be provided.

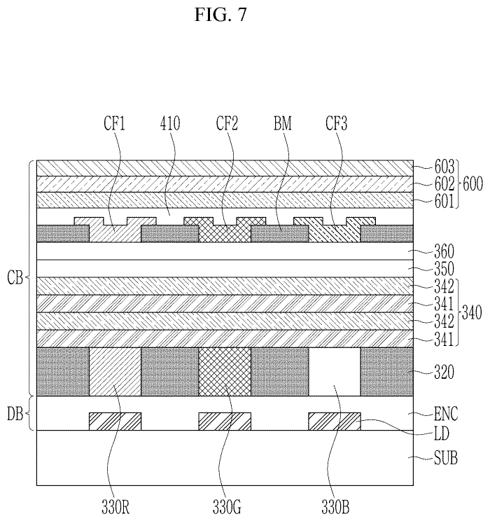

Referring to FIG. 7, the stacking structure disposed below the first overcoat layer 410 corresponds to what is described with reference to FIG. 4. The first layer 340 has a structure in which the first sub-layer 341 and the second sub-layer 342 are stacked repeatedly twice. That is, the first layer 340 has a multilayered structure in which the first sub-layer 341, the second sub-layer 342, the first sub-layer 341, and the second sub-layer 342 are stacked.

The low reflection layer 600 described with reference to FIG. 6 may be disposed on the first overcoat layer 410 in an embodiment of FIG. 7.

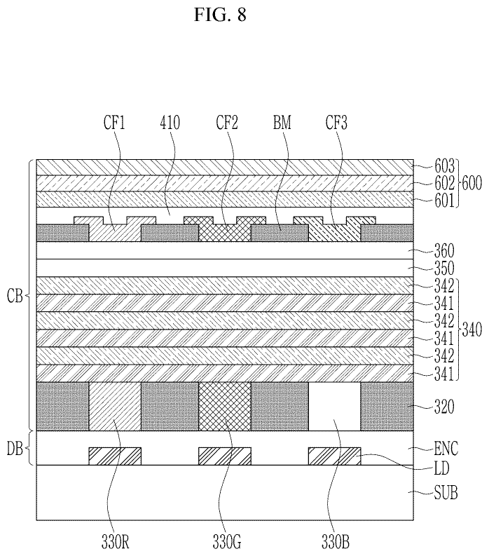

Referring to FIG. 8, the stacking structure disposed below the first overcoat layer 410 corresponds to what is described with reference to FIG. 5. The first layer 340 has a structure in which the first sub-layer 341 and the second sub-layer 342 are stacked repeatedly three times. That is, the first layer 340 has a multilayered structure in which the first sub-layer 341, the second sub-layer 342, the first sub-layer 341, the second sub-layer 342, the first sub-layer 341, and the second sub-layer 342 are stacked.

In an embodiment of FIG. 8, the low reflection layer 600 described with reference to FIG. 6 may be disposed on the first overcoat layer 410.

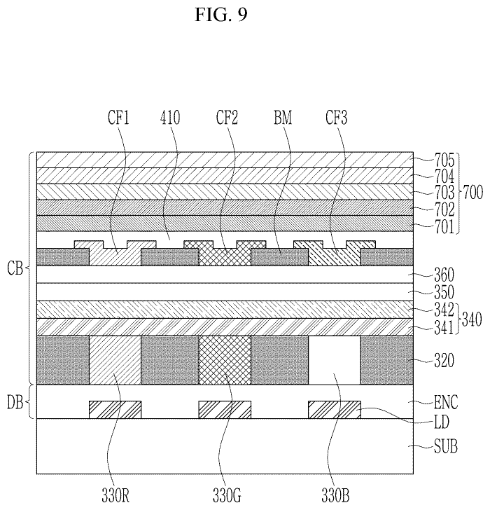

A display panel in an embodiment will now be described with reference to FIG. 9. The stacking structure below the first overcoat layer 410 in an embodiment of FIG. 9 corresponds to what is described with reference to FIG. 3. A constituent element disposed on the first overcoat layer 410 will now be described.

Referring to FIG. 9, a low reflection layer 700 may be disposed on the first overcoat layer 410. The low reflection layer 700 may include a first inorganic layer 701, a second inorganic layer 702, a third inorganic layer 703, a fourth inorganic layer 704, and a third overcoat layer 705 that are sequentially stacked.

The first inorganic layer 701 may be disposed on the first overcoat layer 410. The first inorganic layer 701 may prevent permeation of moisture into the color converting layers 330R and 330G. The refractive index of the first inorganic layer 701 may be about 1.8 to about 2.0. The first inorganic layer 701 may include any types of materials satisfying the above-noted refractive index, e.g., silicon nitride. The thickness of the first inorganic layer 701 may be about 10 nm to about 30 nm.

The second inorganic layer 702 may be disposed on the first inorganic layer 701. The second inorganic layer 702 may prevent oxidization of other stacked layers. The refractive index of the second inorganic layer 702 may be about 1.4 to about 1.5. The second inorganic layer 702 may include any types of materials satisfying the above-noted refractive index, e.g., silicon oxide. The thickness of the second inorganic layer 702 may be about 10 nm to about 30 nm.

The third inorganic layer 703 may be disposed on the second inorganic layer 702. The third inorganic layer 703 may have a relatively high refractive index. In an embodiment, the refractive index of the third inorganic layer 703 may be about 1.8 to about 2.0, for example. The third inorganic layer 703 may include any types of materials satisfying the above-noted refractive index, e.g., silicon nitride. The thickness of the third inorganic layer 703 may be about 100 nm to about 150 nm.

The fourth inorganic layer 704 may be disposed on the third inorganic layer 703. The refractive index of the fourth inorganic layer 704 may be about 1.4 to about 1.5. The fourth inorganic layer 704 may include any types of materials satisfying the above-noted refractive index, e.g., silicon oxide. The thickness of the fourth inorganic layer 704 may be about 10 nm to about 30 nm.

The third overcoat layer 705 may be disposed on the fourth inorganic layer 704. The third overcoat layer 705 may have a relatively low refractive index. In an embodiment, the refractive index of the third overcoat layer 705 may be about 1.25 to about 1.30, and may include any types of materials satisfying the same, for example. The thickness of the third overcoat layer 705 may be about 60 nm to about 110 nm.

The low reflection layer 700 may have a structure in which the first inorganic layer, the second inorganic layer, the third inorganic layer, the fourth inorganic layer, and the third overcoat layer (or an organic layer) are sequentially stacked with respect to the first overcoat layer 410. According to the stacking structure, the reflection of light input toward the display panel from the external light may be reduced, and improved displaying quality may be provided.

Further, the low reflection layer 700 in an embodiment may be formed by a coating process. As no additional film is desired, the process may be simplified.

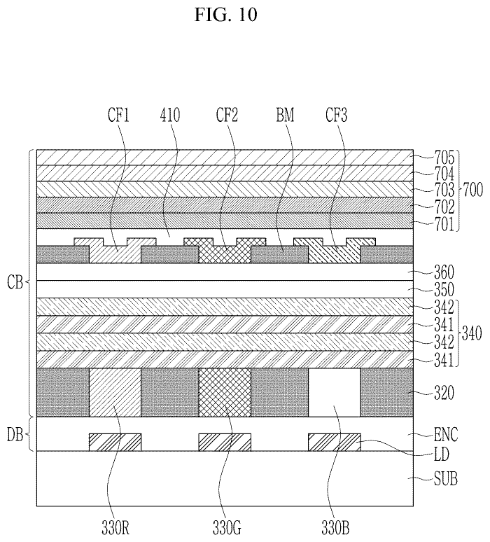

Referring to FIG. 10, the stacking structure disposed below the first overcoat layer 410 corresponds to what is described with reference to FIG. 4. The first layer 340 has a structure in which the first sub-layer 341 and the second sub-layer 342 are stacked repeatedly twice. That is, the first layer 340 may have a multilayered structure in which the first sub-layer 341, the second sub-layer 342, the first sub-layer 341, and the second sub-layer 342 are stacked.

In an embodiment of FIG. 10, the low reflection layer 700 described in FIG. 9 may be disposed on the first overcoat layer 410.

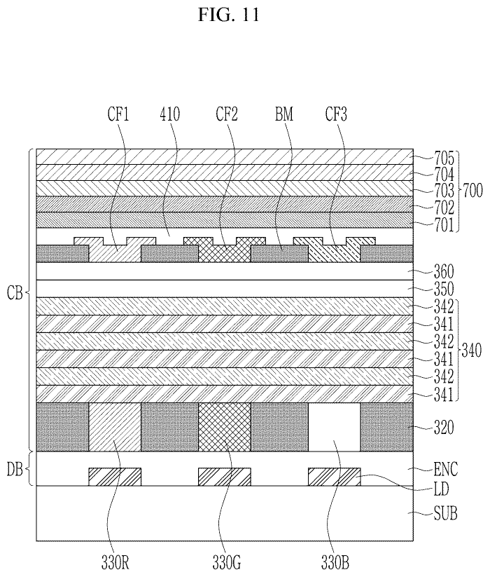

Referring to FIG. 11, the stacking structure disposed below the first overcoat layer 410 corresponds to what is described with reference to FIG. 5. The first layer 340 has a structure in which the first sub-layer 341 and the second sub-layer 342 are stacked repeatedly three times. That is, the first layer 340 has a multilayered structure in which the first sub-layer 341, the second sub-layer 342, the first sub-layer 341, the second sub-layer 342, the first sub-layer 341, and the second sub-layer 342 are stacked.

The low reflection layer 700 described in FIG. 9 may be disposed on the first overcoat layer 410 in an embodiment of FIG. 11.

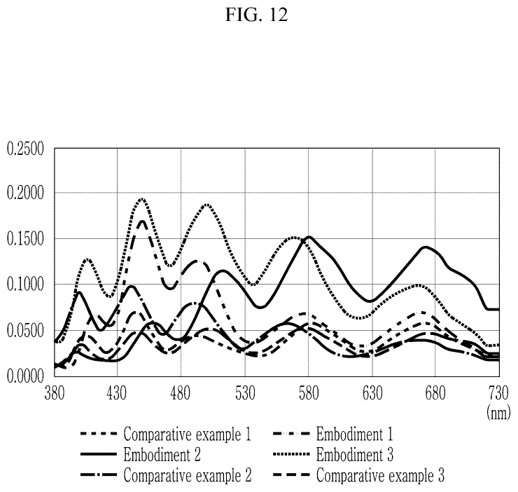

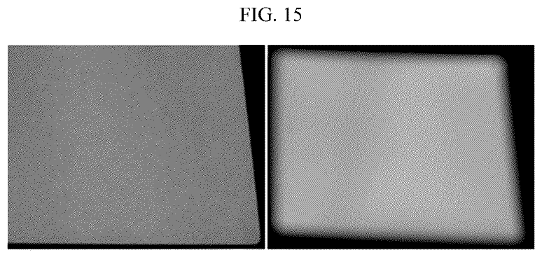

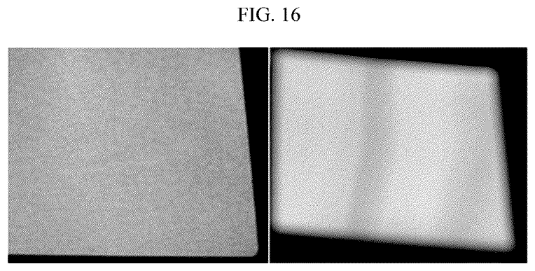

An embodiment and a comparative example will now be described with reference to FIG. 12 to FIG. 16. FIG. 12 to FIG. 14 show efficiency increasing graphs of an embodiment and a comparative example, FIG. 15 shows a comparative example of an image of a display panel, and FIG. 16 shows an embodiment of an image of a display panel.

FIG. 12 to FIG. 14 show light reflectance (Y-axis) with respect to light wavelengths (X-axis).

Referring to FIG. 12, Comparative Example 1 includes a first layer including silicon oxynitride with the thickness of 400 nm, and Comparative Example 2 includes a first sub-layer including silicon oxide with the thickness of 40 nm and a second sub-layer including silicon nitride with the thickness of 40 nm. Comparative Example 3 includes a first sub-layer including silicon oxide with the thickness of 20 nm and a second sub-layer including silicon nitride with the thickness of 20 nm.

Embodiment 1 includes a first sub-layer including silicon oxide with the thickness of 200 nm and a second sub-layer including silicon nitride with the thickness of 200 nm. Embodiment 2 includes a first sub-layer including silicon oxide with the thickness of 100 nm and a second sub-layer including silicon nitride with the thickness of 100 nm. Embodiment 3 includes a first sub-layer including silicon oxide with the thickness of 70 nm and a second sub-layer including silicon nitride with the thickness of 70 nm.

Blue light reflectance and blue light converting rates of Comparative Example 1 (CE1 in Table 1), Embodiment 1 (E1 in Table 1), and Embodiment 3 (E3 in Table 1) from among the comparative example and the embodiments shown in FIG. 12 are expressed in Table 1. Referring to Table 1, it is found in the case of Embodiment 1 and Embodiment 3 that the blue light reflectance on the first layer is increased by about 10%, and the blue light converting rate on the color converting layer is increased by about 1%.

TABLE 1

| | CE1 | E1 | E3 |
|---|---|---|---|
| Blue light reflectance | 5.94% | 15.46% | 17.95% |
| Blue light converting rates | 30.44% | 31.15% | 31.34% |

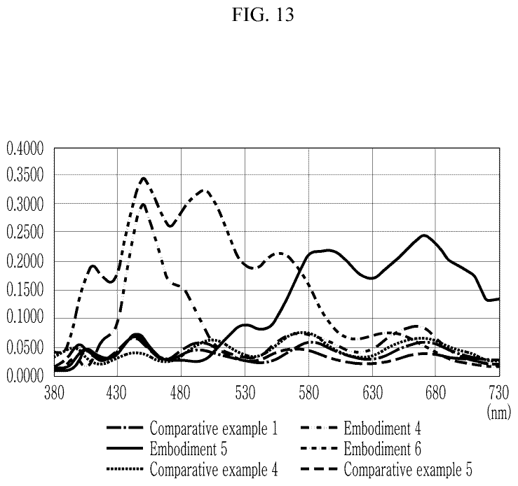

Referring to FIG. 13, Comparative Example 1 includes a first layer including silicon oxynitride with the thickness of 400 nm, and Comparative Example 4 includes a multilayered structure in which a first sub-layer including silicon oxide with the thickness of 40 nm and a second sub-layer including silicon nitride with the thickness of 40 nm are repeated twice. Comparative Example 5 has a multilayered structure in which the first sub-layer including silicon oxide with the thickness of 20 nm and a second sub-layer including silicon nitride with the thickness of 20 nm are repeated twice. Embodiment 4 has a multilayered structure in which the first sub-layer including silicon oxide with the thickness of 200 nm and the second sub-layer including silicon nitride with the thickness of 200 nm are repeated twice. Embodiment 5 has a multilayered structure in which the first sub-layer including silicon oxide with the thickness of 100 nm and the second sub-layer including silicon nitride with the thickness of 100 nm are repeated twice. Embodiment 6 has a multilayered structure in which the first sub-layer including silicon oxide with the thickness of 70 nm and the second sub-layer including silicon nitride with the thickness of 70 nm are repeated twice.

Blue light reflectance and blue light converting rates of Comparative Example 1 (CE1 in Table 2), Embodiment 4 (E4 in Table 1), and Embodiment 6 (E6 in Table 1) from among the comparative example and the embodiments shown in FIG. 13 are expressed in Table 2. Referring to Table 2, it is found in the case of Embodiment 4 and Embodiment 6 that the blue light reflectance on the first layer is increased by about five times to about six times, and the blue light converting rate on the color converting layer is increased by about 2%.

TABLE 2

| | CE1 | E4 | E6 |
|---|---|---|---|
| Blue light reflectance | 5.94% | 27.00% | 32.40% |
| Blue light converting rates | 30.44% | 32.01% | 32.41% |

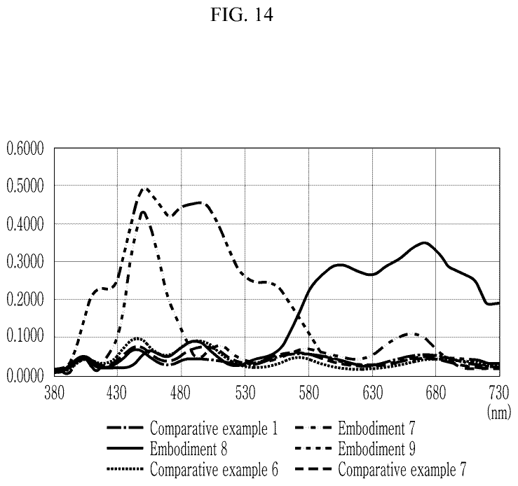

Referring to FIG. 14, Comparative Example 1 includes the first layer including silicon oxynitride with the thickness of 400 nm, and Comparative Example 6 has a multilayered structure in which the first sub-layer including silicon oxide with the thickness of 40 nm and the second sub-layer including silicon nitride with the thickness of 40 nm are repeated three times. Comparative Example 7 has a multilayered structure in which the first sub-layer including silicon oxide with the thickness of 20 nm and the second sub-layer including silicon nitride with the thickness of 20 nm are repeated three times. Embodiment 7 has a multilayered structure in which the first sub-layer including silicon oxide with the thickness of 200 nm and the second sub-layer including silicon nitride with the thickness of 200 nm are repeated three times. Embodiment 8 has a multilayered structure in which the first sub-layer including silicon oxide with the thickness of 100 nm and the second sub-layer including silicon nitride with the thickness of 100 nm are repeated three times. Embodiment 9 has a multilayered structure in which the first sub-layer including silicon oxide with the thickness of 70 nm and the second sub-layer including silicon nitride with the thickness of 70 nm are repeated three times.

Blue light reflectance and blue light converting rates of Comparative Example 1 (CE1 in Table 3), Embodiment 7 (E7 in Table 3), and Embodiment 9 (E9 in Table 3) from among the comparative example and the embodiments shown in FIG. 14 are expressed in Table 3. Referring to Table 3, it is found in the case of Embodiment 7 and Embodiment 9 that the blue light reflectance is increased by about five times to about six times, and the corresponding blue light converting rate is increased by about 3%.

TABLE 3

| | CE1 | E7 | E9 |
|---|---|---|---|
| Blue light reflectance | 5.94% | 37.74% | 46.43% |
| Blue light converting rates | 30.44% | 32.88% | 33.45% |

FIG. 15 shows an image of a display panel including a first layer according to a comparative example. The first layer according to a comparative example includes silicon oxynitride (SiON) with the thickness of 400 nm. FIG. 16 shows an image of a display panel including a first layer. The first layer in an embodiment includes the first sub-layer including silicon oxynitride with the thickness of 300 nm and the second sub-layer including silicon nitride with the thickness of 100 nm. In comparison to FIG. 15 and FIG. 16, it is found in the case of the embodiment that the blue light reflectance is increased. That is, it is found, when including the first layer in an embodiment, that the blue light reflectance is excellent and the amount of the blue light reflected to the color converting layer is resultantly increased. This may be additionally confirmed from Table 4. Regarding Table 4, the first layer includes silicon oxynitride with the thickness of 400 nm according to a comparative example (CE in Table 4). Embodiment 1 (E1 in Table 4) includes the first sub-layer including silicon oxynitride with the thickness of 300 nm and the second sub-layer including silicon nitride with the thickness of 100 nm. Embodiment 2 (E2 in Table 4) includes the first layer formed by stacking the first sub-layer and the second sub-layer of Embodiment 1 repeatedly twice. Embodiment 3 (E3 in Table 4) includes the first layer formed by stacking the first sub-layer and the second sub-layer of Embodiment 1 repeatedly three times. Embodiment 4 (E4 in Table 4) includes the first layer formed by stacking the first sub-layer and the second sub-layer of Embodiment 1 repeatedly four times. Embodiment 5 (E5 in Table 4) includes the first layer formed by stacking the first sub-layer and the second sub-layer of Embodiment 1 repeatedly five times. Embodiment 6 (E6 in Table 4) includes the first layer formed by stacking the first sub-layer and the second sub-layer of Embodiment 1 repeatedly six times.

Referring to Table 4, it is found that the blue light reflectance is increased as the stacking number of times on the first sub-layer and the second sub-layer, and hence, the blue light converting rate of the color converting layer is also increased.

TABLE 4

| | CE | E1 | E2 | E3 | E4 | E5 | E6 |
|---|---|---|---|---|---|---|---|
| Blue light | 5.87% | 6.88% | 6.89% | 6.92% | 6.98% | 7.08% | 7.26% |
| reflectance | | | | | | | |
| Blue light | 30.4% | 30.5% | 30.6% | 30.7% | 30.9% | 31.4% | 32.2% |
| converting | | | | | | | |
| rates | | | | | | | |

By the embodiments, the blue light that is not converted by the color converting layer but is transmitted is reflected to the color converting layer, and the amount of blue light provided to the color converting layer may be increased. Accordingly, the amount of light converted in the color converting layer increases, thereby providing a display device with improved light output efficiency. While this invention has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A display device comprising:
a display unit disposed on a substrate; and
a color converter disposed on the display unit, the color converter including:
a color converting layer and a transmission layer;
a bank disposed between the color converting layer and the transmission layer;
a first layer disposed on the color converting layer, the transmission layer, and the bank, the first layer including:
a first sub-layer with a first refractive index; and
a second sub-layer with a second refractive index;
a second layer disposed on the first layer and having a refractive index smaller than the first refractive index of the first layer;
a third layer disposed on the second layer and having a refractive index greater than the refractive index of the second layer; and
a color filter disposed on the third layer,
wherein the first refractive index is equal to or greater than about 1.4 and less than about 1.8, and
the second refractive index is equal to or greater than about 1.8 and equal to or less than about 2.0.

2. The display device of claim 1, wherein
the first sub-layer has a thickness of about 50 nanometers to about 300 nanometers.

3. The display device of claim 1, wherein
the second sub-layer has a thickness of about 50 nanometers to about 300 nanometers.

4. The display device of claim 1, wherein
the first sub-layer includes silicon oxynitride or silicon oxide.

5. The display device of claim 1, wherein
the second sub-layer includes silicon nitride.

6. The display device of claim 1, wherein
the first sub-layer and the second sub-layer are alternately repeatedly stacked between twice to six times.

7. The display device of claim 6, wherein
the first sub-layer and the second sub-layer are alternately repeatedly stacked twice or three times.

8. The display device of claim 1, further comprising:
a first overcoat layer disposed on the color filter.

9. The display device of claim 8, wherein
the first overcoat layer has a refractive index of about 1.45 to about 1.55, and
the first overcoat layer has a thickness of about 5 micrometers to about 15 micrometers.

10. The display device of claim 8, further comprising:
a low reflection layer disposed on the first overcoat layer.

11. The display device of claim 10, wherein
the low reflection layer includes:
a first organic layer disposed on the first overcoat layer;
a second organic layer disposed on the first organic layer; and
a second overcoat layer disposed on the second organic layer.

12. The display device of claim 11, wherein
the first organic layer has a refractive index of about 1.6 to about 1.7,
the second organic layer has a refractive index of about 1.8 to about 2.0, and
the second overcoat layer has a refractive index of about 1.25 to about 1.30.

13. The display device of claim 11, wherein
the first organic layer has a thickness of about 50 nanometers to about 100 nanometers,
the second organic layer has a thickness of about 100 nanometers to about 150 nanometers, and
the second overcoat layer has a thickness of about 60 nanometers to about 110 nanometers.

14. The display device of claim 10, wherein
the low reflection layer includes:
a first inorganic layer disposed on the first overcoat layer;
a second inorganic layer disposed on the first inorganic layer;
a third inorganic layer disposed on the second inorganic layer;
a fourth inorganic layer disposed on the third inorganic layer; and
a third overcoat layer disposed on the fourth inorganic layer.

15. The display device of claim 14, wherein
the first inorganic layer has a refractive index of about 1.8 to about 2.0,
the second inorganic layer has a refractive index of about 1.4 to about 1.5,
the third inorganic layer has a refractive index of about 1.8 to about 2.0,
the fourth inorganic layer has a refractive index of about 1.4 to about 1.5, and
the third overcoat layer has a refractive index of about 1.25 to about 1.30.

16. The display device of claim 14, wherein
the first inorganic layer has a thickness of about 10 nanometers to about 30 nanometers,
the second inorganic layer has a thickness of about 10 nanometers to about 30 nanometers,
the third inorganic layer has a thickness of about 100 nanometers to about 150 nanometers,
the fourth inorganic layer has a thickness of about 10 nanometers to about 30 nanometers, and
the third overcoat layer has a thickness of about 60 nanometers to about 110 nanometers.

17. The display device of claim 1, wherein
blue light has greater reflectance than red light and green light on the first layer.

18. A display device comprising:
a light-emitting diode disposed on a substrate; and
a color converter disposed on the light-emitting diode, the color converter including:
a color converting layer and a transmission layer;
a bank disposed between the color converting layer and the transmission layer;
a first layer contacting upper sides of the color converting layer, the transmission layer, the first layer including:
a first sub-layer with a first refractive index; and
a second sub-layer with a second refractive index; and
a color filter disposed on the first layer,
wherein the first refractive index is equal to or greater than about 1.4 and less than about 1.8, and
the second refractive index is equal to or greater than about 1.8 and equal to or less than about 2.0.

19. The display device of claim 18, wherein
the display device further includes
a second layer disposed on the first layer and having a refractive index smaller than the first refractive index of the first layer, and
a third layer disposed on the second layer and having a refractive index greater than the refractive index of the second layer.

20. The display device of claim 19, wherein
the second layer has a refractive index of about 1.20 to about 1.30, and
the third layer has a refractive index of about 1.45 to about 1.70.

21. The display device of claim 19, wherein
the second layer has a thickness of about 1 micrometer to about 3 micrometers, and
the third layer has a thickness of about 300 nanometers to about 500 nanometers.

22. The display device of claim 18, wherein
the bank has a thickness of about 6 micrometers to about 12 micrometers.

23. The display device of claim 18, wherein
the first sub-layer and the second sub-layer are alternately repeatedly stacked.
